(19) United States
(12) Patent Application Publication
(10) Pub. No.: US 2022/0230674 A1
(43) Pub. Date: Jul. 21, 2022

(54) READ OPERATION METHOD FOR NON-VOLATILE MEMORY DEVICE TO REDUCE DISTURBANCE

(71) Applicant: MACRONIX INTERNATIONAL CO., LTD., Hsinchu (TW)

(72) Inventors: Chih-Chieh CHENG, Zhubei City (TW); Chun-Chang LU, Yunlin County (TW); Wen-Jer TSAI, Hualien City (TW)

(21) Appl. No.: 17/153,937

(22) Filed: Jan. 21, 2021

(51) Int. Cl. G11C 11/408; G11C 11/4074; G11C 11/4072; G11C 11/4076; G11C 11/409

(52) U.S. Cl. CPC G11C 11/4085; G11C 11/4074; G11C 11/409; G11C 11/4076; G11C 11/4072

(57) ABSTRACT

An operation method for a memory device is provided. The operation method includes: increasing an adjacent word line voltage to a first adjacent word line voltage during a pre-turn on period; and increasing the adjacent word line voltage from the first adjacent word line voltage to a second adjacent word line voltage after the pre-turn on period is finished; wherein the first adjacent word line voltage is lower than the second adjacent word line voltage; the adjacent word line voltage is applied to at least one adjacent word line, and the at least one adjacent word line is adjacent to a selected word line.

### TECHNICAL FIELD

The disclosure relates in general to an operation method for a memory device, and more particularly to a read operation method for a memory device.

### BACKGROUND

For three-dimension (3D) memory devices, after heavy read cycles, e.g. 100K read cycles on a selected word line, adjacent word lines adjacent to the selected word line may suffer read disturbance.

Analysis reveals that when the pre-turn on period of the selected word line is closed, if the pass voltage (Vpass) of the selected word line is lower than the threshold voltages of the selected word line, then the down-coupling effect occurs. This may cause large channel potential difference between the selected word line and adjacent word lines; and has a high vertical electronic field at the adjacent word lines. Hot carrier injection is likely to occur and then read disturbance occurs.

### SUMMARY

According to one embodiment, an operation method for a memory device is provided. The operation method includes: increasing an adjacent word line voltage to a first adjacent word line voltage during a pre-turn on period; and increasing the adjacent word line voltage from the first adjacent word line voltage to a second adjacent word line voltage after the pre-turn on period is finished; wherein the first adjacent word line voltage is lower than the second adjacent word line voltage; the adjacent word line voltage is applied to at least one adjacent word line, and the at least one adjacent word line is adjacent to a selected word line.

According to another embodiment, provided is an operation method for a memory device. The operation method includes: increasing a selected word line voltage to a first adjacent word line voltage during a pre-turn on period; and lowering the selected word line voltage in multi-step lowering voltages from the first adjacent word line voltage to a reference voltage; wherein in lowering the selected word line voltage in the multi-step lowering voltages, voltage steps are at least more than two steps.

According to an alternative embodiment, provided is an operation method for a memory device. The operation method includes: increasing a selected word line voltage to a first selected word line voltage during a pre-turn on period; and lowering the selected word line voltage from first selected word line voltage in a smooth curve between a first timing and a second timing.

### BRIEF DESCRIPTION OF THE DRAWINGS

FIG. 1 shows a functional block diagram of a memory device according to one embodiment of the application.

FIG. 2 shows a 3D circuit diagram of a memory array according to one embodiment of the application.

FIG. 3 shows a read operation waveform diagram of a memory device according to a first embodiment of the application.

FIG. 4 shows comparison of the horizontal electronic field and the vertical electronic field in the prior art and in the first embodiment of the application.

FIG. 5 shows a relationship curve of Vt (threshold voltage) variation to the read counts in the prior art and in the first embodiment of the application.

FIG. 6A and FIG. 6B shows two read operation waveform diagrams of a memory device according to a second embodiment of the application.

FIG. 7 shows comparison of the horizontal electronic field and the vertical electronic field in the prior art and in the second embodiment of the application.

FIG. 8 shows a relationship curve of Vt (threshold voltage) variation to the read counts in the prior art and in the second embodiment of the application.

FIG. 9 shows a read operation waveform diagram of a memory device according to a third embodiment of the application.

FIG. 10 shows comparison of the horizontal electronic field and the vertical electronic field in the prior art and in the third embodiment of the application.

FIG. 11 shows a relationship curve of Vt (threshold voltage) variation to the read counts in the prior art and in the third embodiment of the application.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

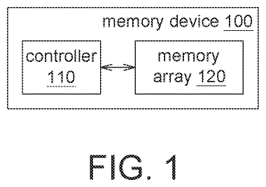

FIG. 1 shows a functional block diagram of a memory device according to one embodiment of the application. The memory device 100 includes: a controller 110 and a memory array 120. The controller 110 is coupled to the memory array 120. The controller 110 controls operations (for example the read operations) of the memory array 120.

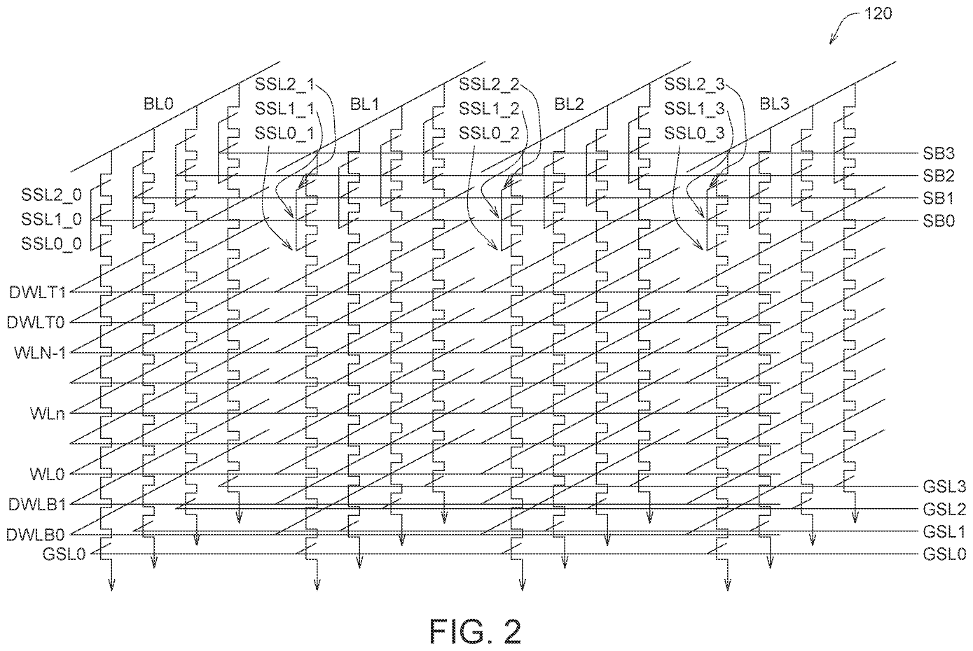

FIG. 2 shows a 3D circuit diagram of a memory array according to one embodiment of the application. The memory array 120 includes a plurality of string select lines (SSLs) SSL0_0 to SSL2_3, a plurality of dummy word lines DWLT1, DWLT0, DWLB1 and DWLB0, a plurality of word lines WL0 to WLN−1 (N being a positive integer), a plurality of bit lines BL0 to BL3, a plurality of global select lines (GSLs) GSL0 to GSL3 and a plurality of memory cells. FIG. 2 is an example, and the application is not limited by this.

Usually, the memory array 120 includes a plurality of memory block each including for example but not limited by four sub-blocks. As shown in FIG. 2, the sub-blocks SB0 to SB3 are independently selected by the SSLs SSL0_0 to SSL2_3 and the GSLs GSL0 to GSL3.

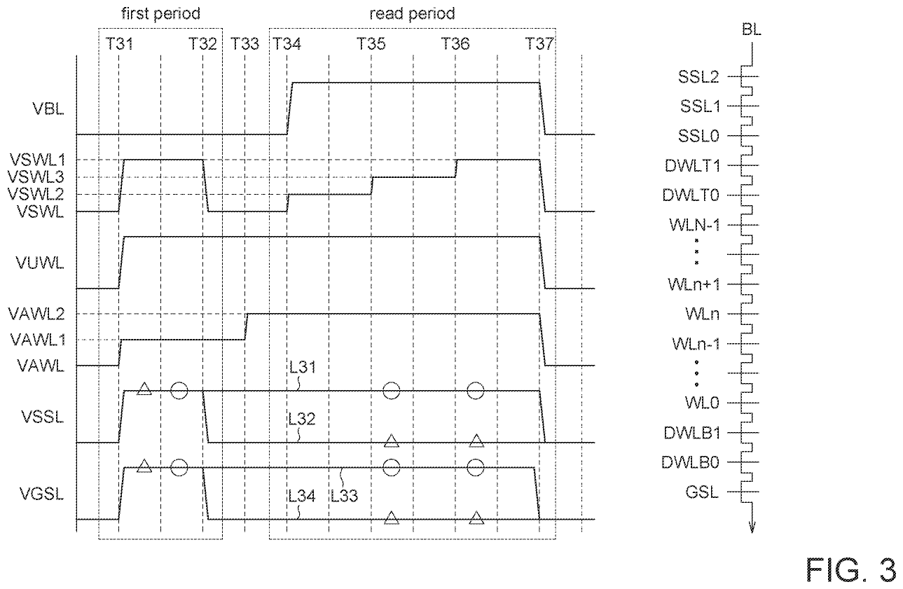

FIG. 3 shows a read operation waveform diagram of a memory device according to a first embodiment of the application. VBL refers to the bit line voltage, VSWL refers to the selected word line voltage, VUWL refers to the unselected word line voltage, VAWL refers to the adjacent word line voltage, VSSL refers to the SSL voltage and VGSL refers to the GSL voltage. In the following, the word line WLn (n being an integer between 0 and N−1) is referred as a selected word line (or a target word line), and the word lines WLn+1 and WLn−1 adjacent to the selected word line WLn are referred as adjacent word lines. The selected word line voltage VSWL is applied to the selected word line and the adjacent word line voltage VAWL is applied to the adjacent word lines.

In the first embodiment of the application, during the pre-turn on period, the bit line voltage VBL is at the low voltage (or said, a reference voltage) (for example but not limited by 0V). In the read period, the bit line voltage VBL is transited to the high voltage (T34). When the read period finishes (T37), the bit line voltage VBL is transited to the low voltage.

In the first embodiment of the application, during the pre-turn on period, the selected word line voltage VSWL is rising to a first selected word line voltage VSWL1 at the timing T31 and is lowering at the timing T32. During the read period, the selected word line voltage VSWL has multi-step voltages (or said, multi-step increasing voltages): a first step voltage (i.e. a second selected word line voltage VSWL2) which is increased from the low voltage at the timing T34, and a second step voltage (i.e, a third selected word line voltage VSWL3) which is increased from the first step voltage (i.e. the second selected word line voltage VSWL2) at the timing T35. At timing 36, the selected word line voltage VSWL is increased from the third selected word line voltage VSWL3 to the first selected word line voltage VSWL1. When the read period is finished (T3), the selected word line voltage VSWL is transited to the low voltage. The second selected word line voltage VSWL2 and the third selected word line voltage VSWL3 are read voltages.

In the first embodiment of the application, during the pre-turn on period, the unselected word line voltage VUWL is rising at the timing T31. When the read period is finished, the unselected word line voltage VUWL is transited to the low voltage.

In the first embodiment of the application, during the pre-turn on period, the adjacent word line voltage VAWL is rising to a first adjacent word line voltage VAWL1 at the timing T31. After the pre-turn on period is finished, the adjacent word line voltage VAWL is rising from the first adjacent word line voltage VAWL1 to a second adjacent word line voltage VAWL2 at the timing T33. When the read period is finished, the adjacent word line voltage VAWL is transited to the low voltage. The first adjacent word line voltage VAWL1 is lower than the second adjacent word line voltage VAWL2; and the second adjacent word line voltage VAWL2 is equal to the unselected word line voltage VUWL.

In the first embodiment of the application, during the pre-turn on period, the adjacent word line voltage VAWL of the adjacent word lines is lower than the selected word line voltage VSWL; and the vertical electronic field on the adjacent word lines during the pre-turn on period is reduced.

In the first embodiment of the application, the rising of the adjacent word line voltage VAWL to the second adjacent word line voltage VAWL2 is later than the end of the pre-turn on period; and thus, the horizontal electronic field on the adjacent word lines is reduced.

In the first embodiment of the application, the first adjacent word line voltage VAWL1 is for example but not limited by, higher than the threshold voltage of the memory cells of the adjacent word lines. For example, the first adjacent word line voltage VAWL1 is between 2V and 5V.

In the first embodiment of the application, the second adjacent word line voltage VAWL2 is corresponding to the pass voltage Vpass. For example, the second adjacent word line voltage VAWL2, which is a sufficient high pass voltage Vpass, is between 6V and 9V (or between 6V and 10V).

In the first embodiment of the application, during the pre-turn on period, the string select line voltage VSSL (labeled by “L31”) of the selected sub-blocks and the string select line voltage VSSL (labeled by “L32”) of the unselected sub-blocks are rising at the timing T31. When the pre-turn on period is finished, the string select line voltage VSSL (labeled by “L32”) of the unselected sub-blocks is lowered at the timing T32. When the read period is finished, the string select line voltage VSSL (labeled by “L31”) of the selected sub-blocks is lowered. During the read period, the string select line voltage VSSL (labeled by “L32”) of the unselected sub-blocks is kept at the low voltage.

In the first embodiment of the application, during the pre-turn on period, the global select line voltage VGSL (labeled by “L33”) of the selected sub-blocks and the global select line voltage VGSL (labeled by “L34”) of the unselected sub-blocks are rising at the timing T31. When the pre-turn on period is finished, the global select line voltage VGSL (labeled by “L34”) of the unselected sub-blocks is lowered at the timing T32. When the read period is finished, the global select line voltage VGSL (labeled by “L33”) of the selected sub-blocks is lowered. During the read period, the global select line voltage VGSL (labeled by “L34”) of the unselected sub-blocks is kept at the low voltage.

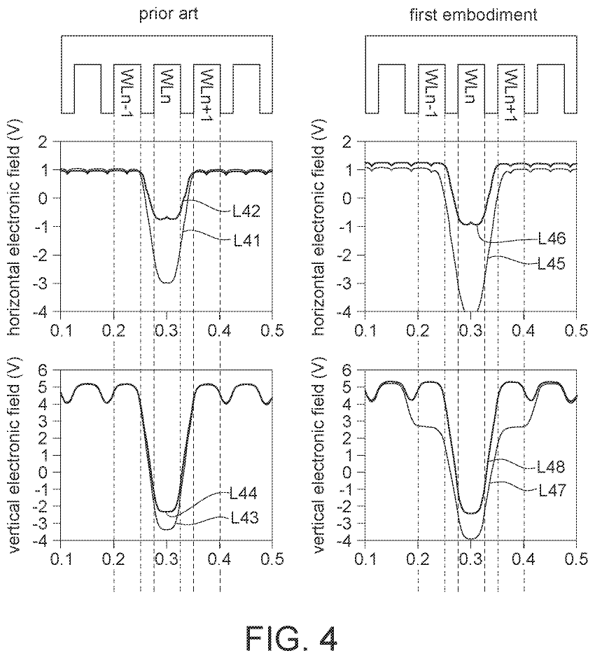

FIG. 4 shows comparison of the horizontal electronic field and the vertical electronic field in the prior art and in the first embodiment of the application. The curve L41 refers to a horizontal electrical field between the channel and ONO (oxide-nitride-oxide) at the selected word line WLn, the adjacent word lines WLn−1, WLn+1 in the prior memory device (not applying the read operations of the first embodiment of the application) when the pre-turn on period is finished. The curve L42 refers to a horizontal electrical field between the channel and ONO at the selected word line WLn, the adjacent word lines WLn−1, WLn+1 in the prior memory device (not applying the read operations of the first embodiment of the application) when the adjacent word line voltage VAWL is increased to the second adjacent word line voltage VAWL2 (at the timing T33).

The curve L43 refers to a vertical electrical field between ONO and the gate at the selected word line WLn, the adjacent word lines WLn−1, WLn+1 in the prior memory device (not applying the read operations of the first embodiment of the application) when the pre-turn on period is finished. The curve L44 refers to a vertical electrical field between ONO and the gate at the selected word line WLn, the adjacent word lines WLn−1, WLn+1 in the prior memory device (not applying the read operations of the first embodiment of the application) when the adjacent word line voltage VAWL is increased to the second adjacent word line voltage VAWL2 (at the timing T33).

The curve L45 refers to a horizontal electrical field between the channel and ONO at the selected word line WLn, the adjacent word lines WLn−1, WLn+1 in the first embodiment of the application when the pre-turn on period is finished. The curve L46 refers to a horizontal electrical field between the channel and ONO at the selected word line WLn, the adjacent word lines WLn−1, WLn+1 in the first embodiment of the application when the adjacent word line voltage VAWL is increased to the second adjacent word line voltage VAWL2 (at the timing T33).

The curve L47 refers to a vertical electrical field between ONO and the gate at the selected word line WLn, the adjacent word lines WLn−1, WLn+1 in the first embodiment of the application when the pre-turn on period is finished. The curve L48 refers to a vertical electrical field between ONO and the gate at the selected word line WLn, the adjacent word lines WLn−1, WLn+1 in the first embodiment of the application when the adjacent word line voltage VAWL is increased to the second adjacent word line voltage VAWL2 (at the timing T33).

By comparing the curves L43 and L47, the read operations of the first embodiment of the application may effectively reduce the vertical electronic field at the adjacent word lines and further reduce the read disturbance.

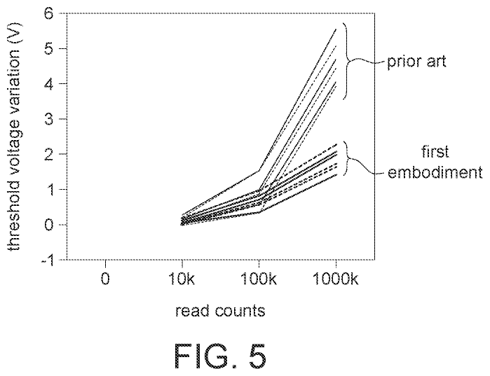

FIG. 5 shows a relationship curve of Vt (threshold voltage) variation to the read counts in the prior art and in the first embodiment of the application. As shown in FIG. 5, the first embodiment of the application may reduce the Vt (threshold voltage) variation and further reduce the read disturbance.

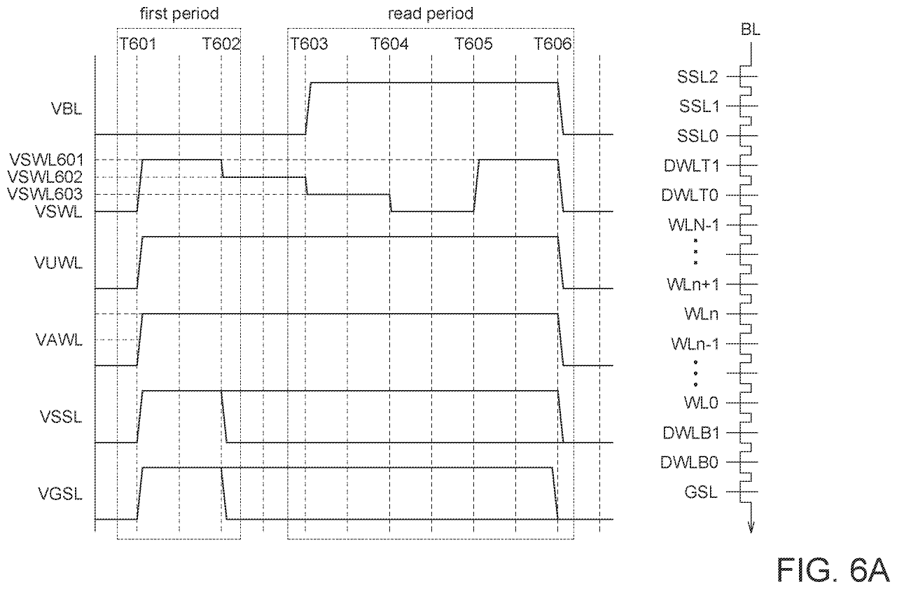

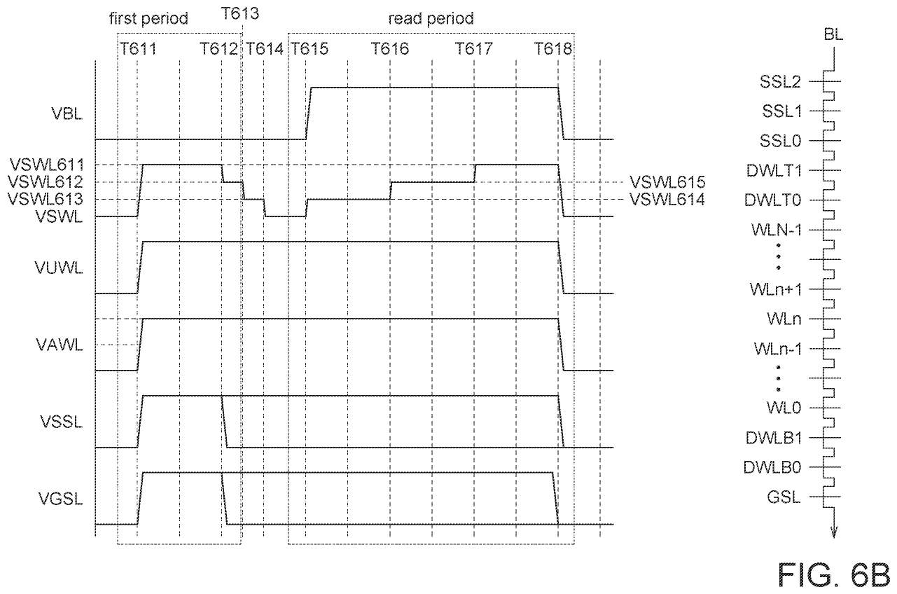

FIG. 6A and FIG. 6B show two read operation waveform diagrams of a memory device according to a second embodiment of the application. In FIG. 6A and FIG. 6B, the bit line voltage VBL, the unselected word line VUWL, the string select line voltage VSSL and the global select line VGSL have waveforms the same or similar to that of the bit line voltage VBL, the unselected word line VUWL, the string select line voltage VSSL and the global select line VGSL in FIG. 3, and thus the details thereof are omitted.

Refer to FIG. 6A. In the second embodiment of the application, during the pre-turn on period, the selected word line voltage VSWL is rising to a first selected word line voltage VSWL601 at the timing T601 and is lowering in multi-step lowering voltages at the timing T602. The selected word line voltage VSWL is lowered from the first selected word line voltage VSWL601 to a second selected word line voltage VSWL602 at the timing T602. The selected word line voltage VSWL is lowered from the second selected word line voltage VSWL602 to a third selected word line voltage VSWL603 at the timing T603. The selected word line voltage VSWL is lowered from the third selected word line voltage VSWL603 to the low voltage at the timing T604. The selected word line voltage VSWL is increased from the low voltage to the first selected word line voltage VSWL601 at the timing T605. The timing T603, T604 and T605 are within the read period. When the read period is finished (T606), the selected word line voltage VSWL is transited to the low voltage. The second selected word line voltage VSWL602 and the third selected word line voltage VSWL603 are read voltages.

Refer to FIG. 6A. In the second embodiment of the application, at beginning of the pre-turn on period, the adjacent word line voltage VAWL is rising; and the adjacent word line voltage VAWL is lowering at the end of the read period.

Refer to FIG. 6B. In the second embodiment of the application, during the pre-turn on period, the selected word line voltage VSWL is rising to a first selected word line voltage VSWL611 at the timing T611 and is lowering in multi-step voltages at the timing T612. The selected word line voltage VSWL is lowered from the first selected word line voltage VSWL611 to a second selected word line voltage VSWL612 at the timing T612. The selected word line voltage VSWL is lowered from the second selected word line voltage VSWL612 to a third selected word line voltage VSWL613 at the timing T613. The selected word line voltage VSWL is lowered from the third selected word line voltage VSWL613 to the low voltage at the timing T614. The multi-step voltage lowering of the selected word line voltage VSWL in FIG. 6B is similar to the multi-step voltage lowering of the selected word line voltage VSWL in FIG. 6A.

The selected word line voltage VSWL is increased from the low voltage to the fourth selected word line voltage VSWL614 at the timing T615. The selected word line voltage VSWL is increased from the fourth selected word line voltage VSWL614 to the fifth selected word line voltage VSWL615 at the timing T616. The selected word line voltage VSWL is increased from the fifth selected word line voltage VSWL615 to the first selected word line voltage VSWL611 at the timing T617. The multi-step voltage increase (during the read period) of the selected word line voltage VSWL in FIG. 6B is similar to the multi-step voltage increase (during the read period) of the selected word line voltage VSWL in FIG. 3.

When the read period is finished (T618), the selected word line voltage VSWL is transited to the low voltage. The second selected word line voltage VSWL612, the third selected word line voltage VSWL613, the fourth selected word line voltage VSWL614 and the fifth selected word line voltage VSWL615 are read voltages.

The adjacent word line voltage VAWL in FIG. 6B has similar waveforms with the adjacent word line voltage VAWL in FIG. 6A and thus the details are omitted.

In the second embodiment of the application, the first selected word line voltage VSWL601/VSWL611 is for example but not limited by, higher than the highest threshold voltage of the memory cells of the selected word line WLn. For example, the first selected word line voltage VSWL601/VSWL611 is between 6V and 10V.

In the second embodiment of the application, in multi-step voltage lowering of the selected word line voltage VSWL, the second selected word line voltage VSWL602/VSWL612 is lower than the first selected word line voltage VSWL601/VSWL611; the third selected word line voltage VSWL603/VSWL613 is lower than the second selected word line voltage VSWL602NSWL612 and so on.

In the second embodiment of the application, in multi-step voltage lowering of the selected word line voltage VSWL, the voltage steps are at least more than two steps.

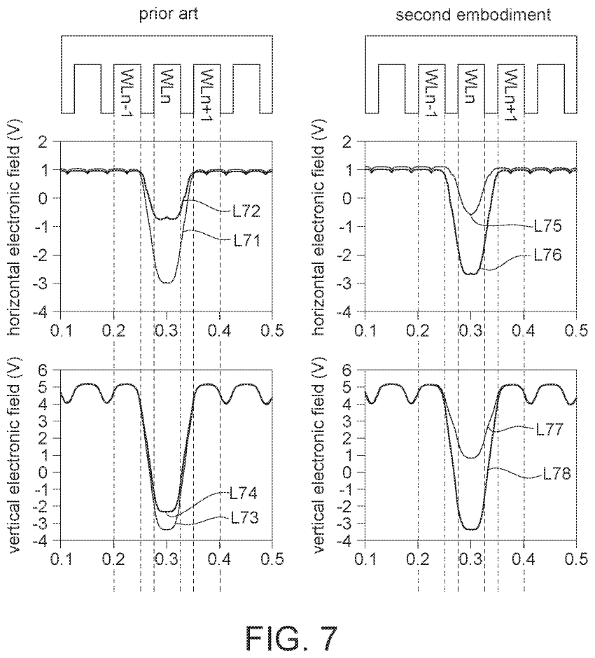

FIG. 7 shows comparison of the horizontal electronic field and the vertical electronic field in the prior art and in the second embodiment of the application. The curve L71 refers to a horizontal electrical field between the channel and ONO at the selected word line WLn, the adjacent word lines WLn−1, WLn+1 in the prior memory device (not applying the read operations of the second embodiment of the application) when the pre-turn on period is finished. The curve L72 refers to a horizontal electrical field between the channel and ONO at the selected word line WLn, the adjacent word lines WLn−1, WLn+1 in the prior memory device (not applying the read operations of the second embodiment of the application) at the timing T605/T615. The curve L73 refers to a vertical electrical field between ONO and the gate at the selected word line WLn, the adjacent word lines WLn−1, WLn+1 in the prior memory device (not applying the read operations of the second embodiment of the application) when the pre-turn on period is finished. The curve L74 refers to a vertical electrical field between ONO and the gate at the selected word line WLn, the adjacent word lines WLn−1, WLn+1 in the prior memory device (not applying the read operations of the second embodiment of the application) at the timing T605/T615. The curve L75 refers to a horizontal electrical field between the channel and ONO at the selected word line WLn, the adjacent word lines WLn−1, WLn+1 in the second embodiment of the application when the pre-turn on period is finished. The curve L76 refers to a horizontal electrical field between the channel and ONO at the selected word line WLn, the adjacent word lines WLn−1, WLn+1 in the second embodiment of the application at the timing T605/T615. The curve L77 refers to a vertical electrical field between ONO and the gate at the selected word line WLn, the adjacent word lines WLn−1, WLn+1 in the second embodiment of the application when the pre-turn on period is finished. The curve L78 refers to a vertical electrical field between ONO and the gate at the selected word line WLn, the adjacent word lines WLn−1, WLn+1 in the second embodiment of the application at the timing T605/T615.

By comparing the curves L71 and L75, the read operations of the second embodiment of the application may effectively reduce the horizontal electronic field at the selected word line WLn and thus reduce the read disturbance. By comparing the curves L73 and L77, the read operations of the second embodiment of the application may effectively reduce the vertical electronic field at the selected word line WLn and thus reduce the read disturbance.

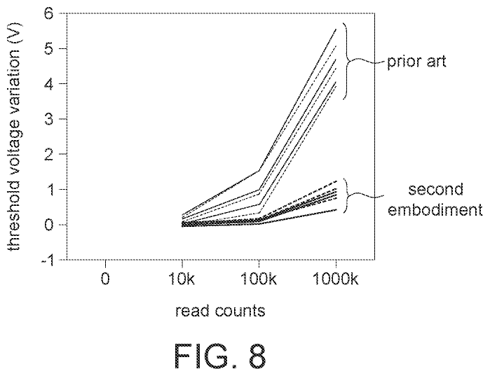

FIG. 8 shows a relationship curve of Vt (threshold voltage) variation to the read counts in the prior art and in the second embodiment of the application. As shown in FIG. 8, the second embodiment of the application may reduce the Vt (threshold voltage) variation and further reduce the read disturbance.

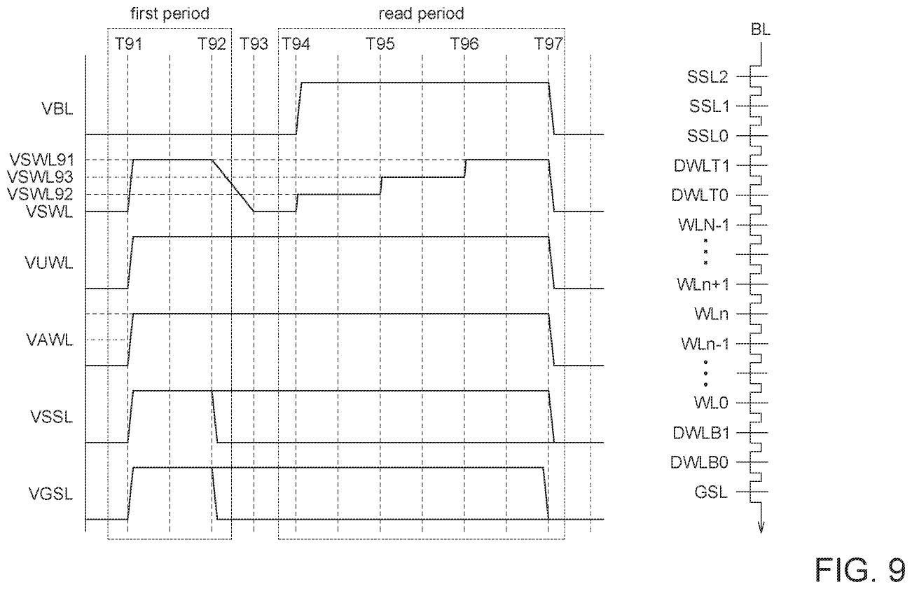

FIG. 9 shows a read operation waveform diagram of a memory device according to a third embodiment of the application. In FIG. 9, the bit line voltage VBL, the unselected word line VUWL, the adjacent word line VAWL, the string select line voltage VSSL and the global select line VGSL have waveforms the same or similar to that of the bit line voltage VBL, the unselected word line VUWL, the adjacent word line VAWL, the string select line voltage VSSL and the global select line VGSL in FIG. 6A and FIG. 6B, and thus the details thereof are omitted.

In the third embodiment of the application, during the pre-turn on period, the selected word line voltage VSWL is rising to a first selected word line voltage VSWL91 at the timing T91. From the timing T92 to the timing T93, the selected word line voltage VSWL is lowered from the first selected word line voltage VSWL91 to the low voltage in a smooth curve. In one possible embodiment of the application, the smooth curve refers to, for example but not limited by, a straight line.

In the third embodiment of the application, the time length between the timing T92 and the timing T93 is longer than 1 μs, for example but not limited by, between 1 μs to 10 μs.

In the third embodiment of the application, during the read period, the selected word line voltage VSWL has multi-step voltages: a first step voltage (i.e. a second selected word line voltage VSWL92) which is increased from the low voltage at the timing T94, and a second step voltage (i.e. a third selected word line voltage VSWL93) which is increased from the first step voltage (i.e. the second selected word line voltage VSWL92) at the timing T95. At timing 36, the selected word line voltage VSWL is increased from the third selected word line voltage VSWL93 to the first selected word line voltage VSWL91. When the read period is finished (T97), the selected word line voltage VSWL is transited to the low voltage. The second selected word line voltage VSWL92 and the third selected word line voltage VSWL93 are read voltages.

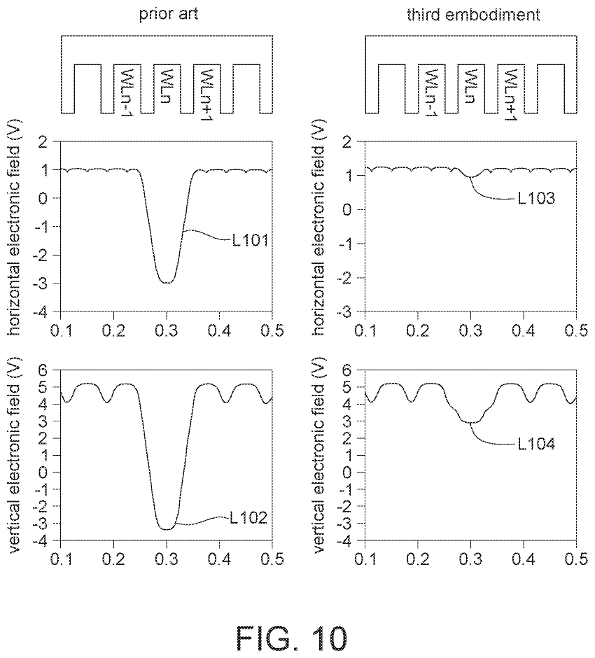

FIG. 10 shows comparison of the horizontal electronic field and the vertical electronic field in the prior art and in the second embodiment of the application. The curve L101 refers to a horizontal electrical field between the channel and ONO at the selected word line WLn, the adjacent word lines WLn−1, WLn+1 in the prior memory device (not applying the read operations of the third embodiment of the application) when the pre-turn on period is finished. The curve L102 refers to a vertical electrical field between ONO and the gate at the selected word line WLn, the adjacent word lines WLn−1, WLn+1 in the prior memory device (not applying the read operations of the third embodiment of the application) when the pre-turn on period is finished. The curve L103 refers to a horizontal electrical field between the channel and ONO at the selected word line WLn, the adjacent word lines WLn−1, WLn+1 in the third embodiment of the application at the timing T93. The curve L104 refers to a vertical electrical field between ONO and the gate at the selected word line WLn, the adjacent word lines WLn−1, WLn+1 in the third embodiment of the application at the timing T93.

By comparing the curves L101, L102, L103 and L104, the read operations of the third embodiment of the application may effectively reduce the horizontal electronic field and the vertical electronic field at the selected word line WLn for reducing the read disturbance.

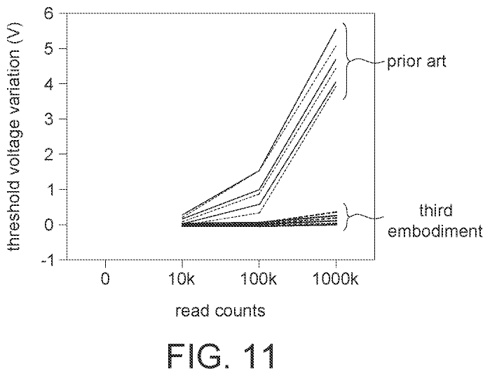

FIG. 11 shows a relationship curve of Vt (threshold voltage) variation to the read counts in the prior art and in the third embodiment of the application, As shown in FIG. 11, the third embodiment of the application may reduce the Vt (threshold voltage) variation and further reduce the read disturbance.

The first embodiment, the second embodiment and the third embodiment may be independently implemented or may be implemented in combination. For example, the first embodiment and the second embodiment may be implemented in combination. Alternatively, the first embodiment and the third embodiment may be implemented in combination. These are within the spirit and the scope of the application.

From the above description, the above embodiments of the application may effectively reduce abnormal read disturbance on the selected word line.

It will be apparent to those skilled in the art that various modifications and variations can be made to the disclosed embodiments. It is intended that the specification and examples be considered as exemplary only, with a true scope of the disclosure being indicated by the following claims and their equivalents.

1. An operation method for a memory device, the operation method including:
increasing an adjacent word line voltage to a first adjacent word line voltage during a first period; and
increasing the adjacent word line voltage from the first adjacent word line voltage to a second adjacent word line voltage during a period from time when the first period is finished till time before a read period is started;
wherein the first adjacent word line voltage is lower than the second adjacent word line voltage;
the adjacent word line voltage is applied to at least one adjacent word line, the at least one adjacent word line is adjacent to a selected word line, the first adjacent word line voltage is higher than a threshold voltage of a plurality of memory cells on the at least one adjacent word line; and the second adjacent word line voltage is corresponding to a pass voltage.

2. The operation method according to claim 1, wherein during the first period, the adjacent word line voltage is lower than a selected word line voltage of the selected word line.

3. (canceled)

4. The operation method according to claim 1, further including:
during the first period, rising a selected word line voltage to a first selected word line voltage and lowering the selected word line voltage when the first period is finished; and
during a read period, increasing the selected word line voltage in multi-step voltages.

5. The operation method according to claim 4, wherein during the read period, the multi-step voltages of the selected word line voltage are read voltages.

6. The operation method according to claim 1, further including:
increasing a selected word line voltage to a first selected word line voltage during the first period; and
lowering the selected word line voltage in multi-step lowering voltages from the first selected word line voltage to a reference voltage.

7. The operation method according to claim 6, wherein in lowering the selected word line voltage in the multi-step lowering voltages, voltage steps are at least more than two steps.

8. The operation method according to claim 7, wherein
during a read period, the selected word line voltage is lowered from a first selected word line voltage to a second selected word line voltage;
during the read period, the selected word line voltage is lowered from the second selected word line voltage to a third selected word line voltage;
the second selected word line voltage and the third selected word line voltage are read voltages.

9. The operation method according to claim 8, wherein the first selected word line voltage is higher than a highest threshold voltage of a plurality of memory cells of a selected word line.

10. The operation method according to claim 9, further including:
increasing the selected word line voltage from the reference voltage in multi-step increasing voltages during the read period.

11. The operation method according to claim 10, wherein in increasing the selected word line voltage in the multi-step increasing voltages, the multi-step increasing voltages of the selected word line voltage are read voltages.

12. The operation method according to claim 1, further including:
increasing a selected word line voltage to a first selected word line voltage during the first period; and
lowering the selected word line voltage from first selected word line voltage in a smooth curve between a first timing and a second timing, wherein the smooth curve is a straight line.

13. The operation method according to claim 12, wherein a time length between the first timing to the second timing is longer than a predetermined time.

14. An operation method for a memory device, the operation method including:
increasing a selected word line voltage to a first selected word line voltage during a first period; and
lowering the selected word line voltage in multi-step lowering voltages from the first selected word line voltage to a reference voltage;
wherein in lowering the selected word line voltage in the multi-step lowering voltages, voltage steps are at least more than two steps;
wherein after lowering the selected word line voltage in the multi-step lowering voltages, the selected word line voltage is increased in multi-step increasing voltages; and
wherein the first selected word line voltage is higher than a highest threshold voltage of a plurality of memory cells of a selected word line.

15. The operation method according to claim 14, wherein
during a read period, the selected word line voltage is lowered from the first selected word line voltage to a second selected word line voltage;
during the read period, the selected word line voltage is lowered from the second selected word line voltage to a third selected word line voltage;
the second selected word line voltage and the third selected word line voltage are read voltages.

16. (canceled)

17. The operation method according to claim 14, further including:
increasing the selected word line voltage from the reference voltage in multi-step increasing voltages during the read period.

18. The operation method according to claim 17, wherein in increasing the selected word line voltage in multi-step increasing voltages, the multi-step increasing voltages of the selected word line voltage are read voltages.

19. An operation method for a memory device, the operation method including:
increasing a selected word line voltage to a first selected word line voltage during a first period; and
lowering the selected word line voltage from the first selected word line voltage in a smooth curve between a first timing and a second timing, wherein the smooth curve is a straight line, the first timing is within the first period, the second timing is within a period from time when the first period is finished till time before a read period is started; and the first selected word line voltage is higher than a highest threshold voltage of a plurality of memory cells of a selected word line.

20. The operation method according to claim 19, wherein a time length between the first timing to the second timing is longer than a predetermined time.
